(19) United States
(12) Patent Application Publication
(10) Pub. No.: US 2015/0084081 A1
(43) Pub. Date: Mar. 26, 2015

(54) METHOD FOR MANUFACTURING LIGHT-EMITTING DEVICE AND LIGHT-EMITTING DEVICE MANUFACTURED USING SAME

(71) Applicant: KOREA UNIVERSITY RESEARCH AND BUSINESS FOUNDATION, Seoul (KR)

(72) Inventors: Tae geun Kim, Seongnam-si (KR); Kyeong-heon Kim, Seoul (KR)

(21) Appl. No.: 14/395,874

(22) PCT Filed: Jan. 10, 2013
(86) PCT No.: PCT/KR2013/000206

§ 371 Date: Oct. 21, 2014

(30) Foreign Application Priority Data
Feb. 16, 2012 (KR) 10-2012-0015703

(51) Int. Cl. H01L 33/22; H01L 33/42; H01L 33/60

(52) U.S. Cl. CPC H01L 33/22; H01L 33/60; H01L 33/42; H01L 2933/0016; H01L 2933/0058; H01L 2933/0091
USPC 257/98; 438/27

(57) ABSTRACT

The present invention relates to a method for manufacturing a light-emitting device and the light-emitting device manufactured using same, which can reduce manufacturing costs, form nanopatterns in a large area, and increase light extraction efficiency. One embodiment of the present invention discloses the method for manufacturing a light-emitting device, comprising: a light-emitting structure preparation step for preparing a light-emitting structure including a first conductive semiconductor layer, an active layer, and a second conductive semiconductor layer, which are formed sequentially; a light extraction layer formation step for forming the upper part of the second conductive semiconductor layer as a light extraction layer having an uneven pattern; a dipping step for dipping the light-emitting structure having the light extraction layer in a solution in which nanomaterials are dispersed; and an adsorption step for adsorbing the nanomaterials to the light extraction layer.

### TECHNICAL FIELD

The present invention relates to a method for manufacturing a light-emitting device and a light-emitting device manufactured using the same, and more particularly, to a method for manufacturing a light-emitting device capable of reducing manufacturing costs, forming nanopatterns in a large area, and increasing light extraction efficiency, and a light-emitting device manufactured using the same.

### BACKGROUND ART

A light-emitting device is a device to emit light to outside by converting electric energy into light energy. As an example of such light-emitting device, there is a light-emitting diode (LED).

The light-emitting diode is a semiconductor device capable of generating light having various types of colors, as holes and electrons are recombined with each other at a junction region between a ‘p’-type semiconductor and an ‘n’-type semiconductor when a voltage is applied thereto. The light-emitting diode has been used, since 2000, in all areas of our daily lives such as lighting of high brightness and white color, after a blue light-emitting diode was developed in 1993 by Japanese Nakamura by using a nitride gallium-based processing technique. Main technique of such light-emitting diode is to enhance extraction of light, and research on enhancing light extraction from a chip of the light-emitting diode is being optimized by epitaxial processing technique and chip processing technique. In order for a performance index of a light-emitting diode of a white color to have 150 lm/W or more, the light-emitting diode of a white color should have light extraction efficiency of 90% or more. However, in enhancing light extraction efficiency, there is a basic problem that light generated from an active layer inside a chip of the light-emitting diode is totally reflected due to a difference of refractive indexes between the active layer and a peripheral layer. Once light is totally reflected, the light is undesirably adsorbed into the chip to thus be converted into thermal energy. As a result, optical loss may occur. Accordingly, research on preventing a total reflection of light is continuously ongoing.

As technique to reduce such total reflection of light, surface roughness technique, refractive index matching technique for extracting most of light generated in the active layer to outside by gradually decreasing a refractive index matching of a layer deposited on a nitride semiconductor so as to smoothly extract photons, etc. are being developed.

As the surface roughness technique, a method capable of enhancing light extraction efficiency by reducing a total reflection at a boundary between a transparent electrode and external air is being spotlighted. According to the method, the surface of the transparent electrode is made to be rough by synthesizing nano-sized materials such as metal clusters, silica nanoparticles and polystyrene beads, or by etching a pattern formed by a laser holo lithography process. However, in case of the laser holo lithography process, it is difficult to form a nano-sized pattern. Further, in case of a nanoparticle synthesis, it is difficult to self-align nanoparticles on a large area. As another example of the surface roughness technique, nano imprint technique of several hundreds of nano size may be used for surface roughness of the transparent electrode. However, in case of using the nano imprint technique, it is difficult to form roughness having a uniform nano size.

As an example of the refractive index matching technique, there is technique for changing a refractive index of a transparent electrode using a nano tip on which Ga has been doped, or an SiO₂ deposition using liquid phase deposition technique. As the transparent electrode, indium tin oxide (ITO) having high optical transmittance is generally used. However, since the ITO has a high refractive index of 2.0, a difference between a refractive index (1.0) of external air and the refractive index (2.0) of the ITO is increased. Such large difference between refractive indexes may result in a total reflection of light, thereby reducing light extraction efficiency.

### DISCLOSURE OF THE INVENTION

Therefore, an object of the present invention is to provide a method for manufacturing a light-emitting device capable of reducing manufacturing costs, forming nanopatterns in a large area, and increasing light extraction efficiency, and a light-emitting device manufactured using the same.

To achieve these and other advantages and in accordance with the purpose of the present invention, as embodied and broadly described herein, there is provided a method for manufacturing a light-emitting device, including: a light-emitting structure preparation step for preparing a light-emitting structure including a first conductive semiconductor layer, an active layer, and a second conductive semiconductor layer, which are formed sequentially; a light extraction layer formation step for forming an upper part of the second conductive semiconductor layer as a light extraction layer having an uneven pattern; a dipping step for dipping the light-emitting structure having the light extraction layer in a solution in which nanomaterials have been dispersed; and an adsorption step for adsorbing the nanomaterials to the light extraction layer, wherein in the adsorption step, the nanomaterials are partially adsorbed to the light extraction layer such that a nanopattern having a plurality of uneven portions is formed on the light extraction layer.

The adsorption step may be performed by a thermal processing method.

In the dipping step, transparent materials may be used as the nanomaterials.

The nanomaterials may be formed of carbon nano tubes or graphenes.

A convex part of the uneven pattern may have a triangular conical shape.

The method may further include forming an electrode on the light extraction layer after the adsorption step.

In the light-emitting structure preparation step, a transparent conductive layer and a reflective layer may be further formed, sequentially on one surface of the first conductive semiconductor layer opposite to another surface thereof where the active layer has been formed.

The method may further include a support substrate attachment step for further forming an adhesive layer and a support substrate, sequentially on one surface of the reflective layer opposite to another surface thereof where the transparent conductive layer has been formed.

To achieve these and other advantages and in accordance with the purpose of the present invention, as embodied and broadly described herein, there is also provided a light-emitting device manufactured by the method for manufacturing a light-emitting device, the light-emitting device including: a first conductive semiconductor layer; an active layer formed on the first conductive semiconductor layer; a second conductive semiconductor layer formed on the active layer, and including a light extraction layer having an uneven pattern at an upper part thereof; and a nanopattern formed as nanomaterials are partially adsorbed to the light extraction layer, wherein the nanopattern forms a plurality of uneven portions on the light extraction layer.

The nanomaterials may be transparent materials.

The nanomaterials may be formed of carbon nano tubes or graphenes.

A convex part of the uneven pattern may have a triangular conical shape.

The light-emitting device, manufactured by the method for manufacturing a light-emitting device according to the present invention, may further include an electrode formed on the light extraction layer.

The light-emitting device, manufactured by the method for manufacturing a light-emitting device according to the present invention, may further include a transparent conductive layer and a reflective layer formed sequentially on one surface of the first conductive semiconductor layer opposite to another surface thereof where the active layer has been formed.

The light-emitting device, manufactured by the method for manufacturing a light-emitting device according to the present invention, may further include an adhesive layer and a support substrate sequentially formed on one surface of the reflective layer opposite to another surface thereof where the transparent conductive layer has been formed.

The first conductive type may be a ‘p’-type, and the second conductive type may be an ‘n’-type.

### Advantageous Effects

In the method for manufacturing a light-emitting device according to an embodiment of the present invention and the light-emitting device manufactured using the same, the nanomaterials are partially adsorbed to the light extraction layer, by the dipping step for dipping the light-emitting structure to the solution where the nanomaterials have been dispersed, and by the adsorption step performed by a thermal processing method. As a result, the nanopattern can be easily formed on the light extraction layer, and a refraction point due to the nanopattern as well as a refraction point due to the light extraction layer having an uneven pattern can be formed.

Thus, in the method for manufacturing a light-emitting device according to an embodiment of the present invention and the light-emitting device manufactured using the same, the nanopattern can be formed on a light-emitting device of a large area, and light extraction efficiency with respect to light generated from the active layer can be more enhanced.

Further, in the method for manufacturing a light-emitting device according to an embodiment of the present invention and the light-emitting device manufactured using the same, the nanopattern can be formed by selecting the nanomaterials from transparent materials having excellent conductivity, a refractive index of 1.5˜1.6 and a flexible characteristic, e.g., carbon nano tubes or graphenes.

Thus, in the method for manufacturing a light-emitting device according to an embodiment of the present invention and the light-emitting device manufactured using the same, formation of the electrode can be minimized or omitted. Further, since a current can be rapidly transferred in a distributed manner without being concentrated on a specific point, thermal stability can be maintained. When compared with the conventional case using an ITO having a refractive index of 2.0, a total reflection of light generated from the active layer can be more reduced. Thus, light extraction efficiency can be more enhanced, and a flexible light-emitting device can be implemented.

### BRIEF DESCRIPTION OF THE DRAWINGS

FIG. 1 is a flowchart illustrating a method for manufacturing a light-emitting device according to an embodiment of the present invention;

FIGS. 2A to 2F are perspective views illustrating the method for manufacturing a light-emitting device of FIG. 1;

FIG. 3 is a sectional view of a light-emitting device according to an embodiment of the present invention;

FIG. 4 is a sectional view illustrating part ‘A’ in FIG. 3; and

FIG. 5 is a sectional view illustrating another embodiment of the light-emitting device of FIG. 3.

### MODES FOR CARRYING OUT THE PREFERRED EMBODIMENTS

Hereinafter, the present invention will be explained in more detail with reference to the attached drawings.

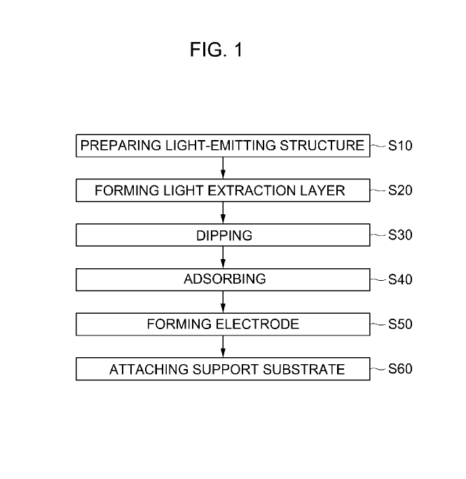

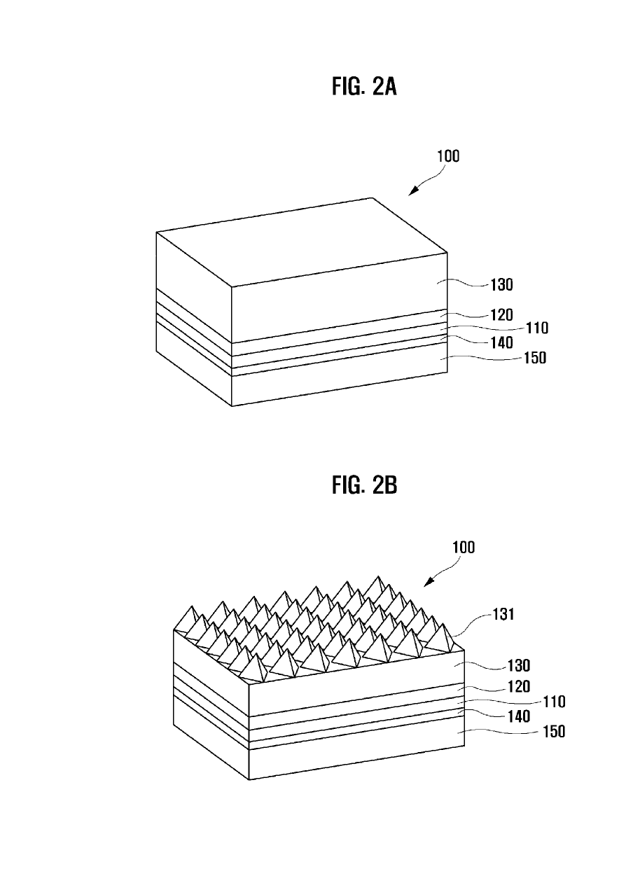

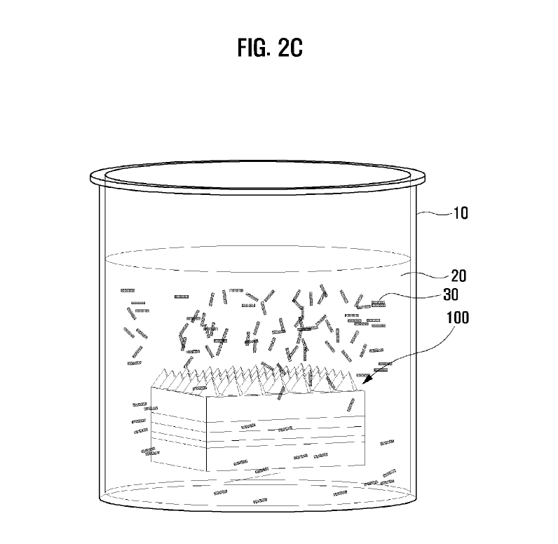

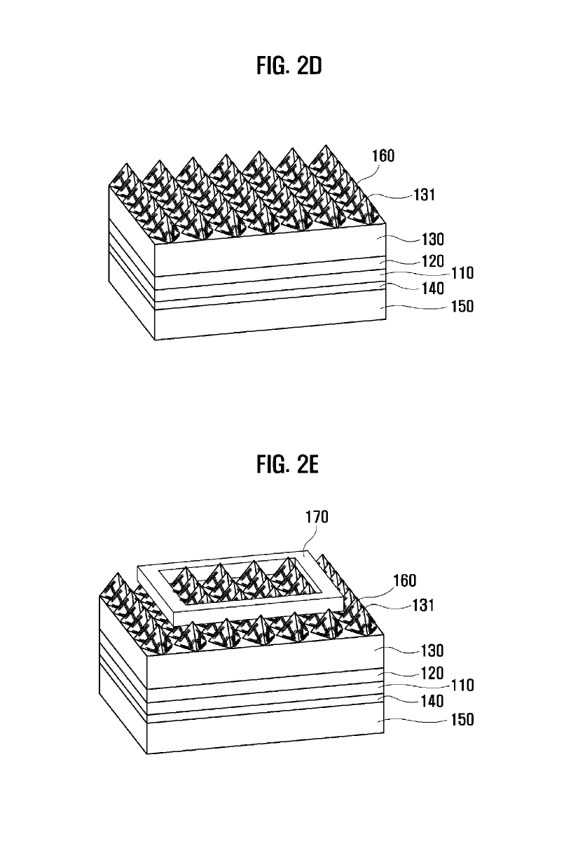

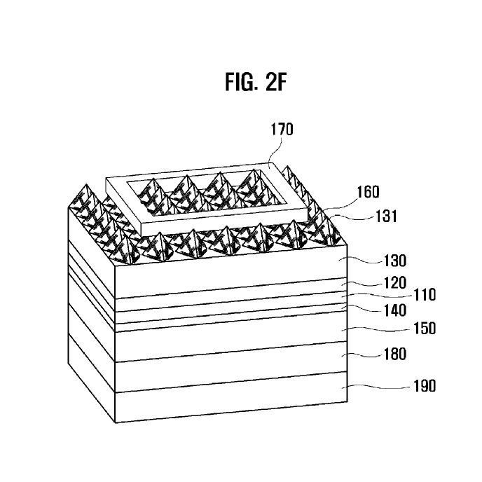

FIG. 1 is a flowchart illustrating a method for manufacturing a light-emitting device according to an embodiment of the present invention, and FIGS. 2A to 2F are perspective views illustrating the method for manufacturing a light-emitting device of FIG. 1.

Referring to FIG. 1, the method for manufacturing a light-emitting device according to an embodiment of the present invention includes a light-emitting structure preparation step (S10), a light extraction layer formation step (S20), a dipping step (S30), an adsorption step (S40), an electrode formation step (S50) and a support substrate attachment step (S60).

Referring to FIG. 2A, the light-emitting structure preparation step (S10) is a step for preparing a light-emitting structure 100 including a first conductive semiconductor layer 110, an active layer 120, and a second conductive semiconductor layer 130, which are formed sequentially.

The first conductive semiconductor layer 110 may be implemented as a ‘p’-type semiconductor layer. The ‘p’-type semiconductor layer may be selected from semiconductor materials having a composition formula of InₓAl_{y}Ga_{1-x-y}N (0≦x≦1, 0≦y≦1, 0≦x+y≦1), e.g., InAlGaN, GaN, AlGaN,AlInN, InGaN, AlN, InN, etc. A ‘p’-type dopant such as Mg, Zn, Ca, Sr and Ba may be doped onto the ‘p’-type semiconductor layer.

The active layer 120 is formed on the first conductive semiconductor layer 110, and may be formed of materials including a semiconductor material having a composition formula of InₓAl_{y}Ga_{1-x-y}N (0≦x≦1, 0≦y≦1, 0≦x+y≦1), for example. The active layer 120 may have one of a single quantum well structure, a multi quantum well (MQW) structure, a quantum point structure and a quantum line structure.

The active layer 120 may generate light by energy generated when electrons and holes of the first conductive semiconductor layer 110 and the second conductive semiconductor layer 130 are recombined with each other.

The second conductive semiconductor layer 130 is formed on the active layer 120, and may be implemented as an ‘n’-type semiconductor layer. The ‘n’-type semiconductor layer may be selected from semiconductor materials having a composition formula of InₓAl_{y}Ga_{1-x-y}N (0≦x≦1, 0≦y≦1, 0≦x+y≦1), e.g., InAlGaN, GaN, AlGaN, AlInN, InGaN, AlN, InN, etc. An ‘n’-type dopant such as Si, Ge and Sn may be doped on the ‘n’-type semiconductor layer.

In the light-emitting structure preparation step (S10), a transparent conductive layer 140 and a reflective layer 150 may be further formed, sequentially on one surface of the first conductive semiconductor layer 110 opposite to another surface thereof where the active layer 120 has been formed. The transparent conductive layer 140 makes a current uniformly flow to the first conductive semiconductor layer 110. The transparent conductive layer 140 may be configured as a transparent conducting oxide (TCO) formed of a transparent conductive thin film layer having a metal such as In, Sn and Zn as a host material. The reflective layer 150 may include reflecting materials such as Ag, Ni, Al, Rh, Pd, Ir, Ru, Mg, Zn, Pt and Au, such that light generated from the active layer 120 is emitted to outside of the second conductive semiconductor layer 130.

Referring to FIG. 2B, the light extraction layer formation step (S20) is a step for forming the upper part of the second conductive semiconductor layer 130 as a light extraction layer 131 having an uneven pattern. The light extraction layer formation step (S20) may be performed by a texturing method for texturing an upper surface of the second conductive semiconductor layer 130, or an etching method for etching an upper part of the second conductive semiconductor layer 130. A convex part of the uneven pattern of the light extraction layer 131 may have a triangular conical shape. However, the present invention is not limited to this. The uneven pattern of the light extraction layer 131 generates a refraction point for emitting light generated from the active layer 120 to outside without being totally reflected, thereby enhancing light emission efficiency.

Referring to FIG. 2C, the dipping step (S30) is a step for dipping the light-emitting structure 100 were the light extraction layer 131 has been formed, in a solution 20 where nanomaterials 30 have been dispersed. The solution 20 may be an aqueous solution, and is filled in a container 10 in advance. The nanomaterials 30 may be transparent materials, e.g., carbon nano tubes or graphenes. The carbon nano tubes or graphenes are transparent, have excellent conductivity, and have low a refractive index of 1.5˜1.6. Such carbon nano tubes and graphenes may serve to minimize or omit formation of an electrode 170, and may allow a current to be rapidly transferred in a distributed manner without being concentrated on a specific point. Thus, thermal stability can be maintained. Further, the carbon nano tubes and graphenes may serve to reduce a total reflection of light generated from the active layer 120 when the light is emitted to air, thereby enhancing light extraction efficiency. Besides, the carbon nano tubes and graphenes may allow a light-emitting device to be applicable to an flexible electronic device, due to their flexible characteristics.

Referring to FIG. 2D, the adsorption step (S40) is a step for adsorbing the nanomaterials 30 to the light extraction layer 131.

More specifically, in the adsorption step (S40), the light-emitting structure 100 is taken out of the solution 20 where the nanomaterials 30 have been dispersed, and then is thermally-processed by a thermal-processing method so that the solution can be evaporated from the light-emitting structure 100. As a result, the nanomaterials are partially adsorbed to the light extraction layer 131 having an uneven pattern, an easily-insertable region of the light-emitting structure 100. A nanopattern 160, formed as the nanomaterials 30 have been partially adsorbed to the light extraction layer 131 having an uneven pattern, forms a plurality of uneven portions on the light extraction layer 131. As a result, an additional refraction point due to the nanopattern 160, as well as a refraction point due to the light extraction layer 131 having an uneven pattern, can be formed. Thus, light extraction efficiency with respect to light generated from the active layer 120 can be more enhanced.

Referring to FIG. 2E, the electrode formation step (S50) is a step for forming an electrode 170 on the light extraction layer 131. The electrode 170 may be configured as a single layer or multi layers formed of a material selected from the group consisting of conducting materials for supplying a current to the second conductive semiconductor layer 130, e.g., Ti, Cr, Al, Cu and Au.

Referring to FIG. 2F, the support substrate attachment step (S60) is a step for further forming an adhesive layer 180 and a support substrate 190, sequentially on one surface of the reflective layer 150 opposite to another surface thereof where the transparent conductive layer 140 has been formed. The adhesive layer 180 for attaching the support substrate 190 to the reflective layer 150 may be configured to have a single layer structure or a multi-layer structure, the structure including at least one of Ti, Au, Sn, Ni, Cr, Ga, In, Bi, Cu, Ag and Ta, metallic materials having an excellent bonding characteristic. The adhesive layer 180 may not be formed in a case where the support substrate 190 is formed by a plating or deposition method rather than a bonding method. The support substrate 190 supports the light-emitting structure 100, and applies a voltage to the light-emitting structure 100 together with the electrode 170. The support substrate 190 may be formed of at least one of a conducting material (e.g., Cu, Au, Ni, Mo and Cu-W) and a carrier wafer (e.g., Si, Ge, GaAs, ZnO, Sic, etc.), such that a current flows to the first conductive semiconductor layer 110.

In the method for manufacturing a light-emitting device according to an embodiment of the present invention, the nanomaterials 30 are partially adsorbed to the light extraction layer 131, by the dipping step (S30) for dipping the light-emitting structure 100 to the solution 20 where the nanomaterials 30 have been dispersed, and by the adsorption step (S40) performed by a thermal processing method. As a result, the nanopattern 160 can be easily formed on the light extraction layer 131, and a refraction point due to the nanopattern 160 as well as a refraction point due to the light extraction layer 131 having an uneven pattern can be formed.

Thus, in the method for manufacturing a light-emitting device according to an embodiment of the present invention, the nanopattern 160 can be formed on a light-emitting device of a large area, and light extraction efficiency with respect to light generated from the active layer 120 can be more enhanced.

Further, in the method for manufacturing a light-emitting device according to an embodiment of the present invention, the nanopattern 160 can be formed by selecting the nanomaterials 30 from transparent materials having excellent conductivity, a refractive index of 1.5˜1.6 and a flexible characteristic, e.g., carbon nano tubes or graphenes.

Thus, in the method for manufacturing a light-emitting device according to an embodiment of the present invention, formation of the electrode 170 can be minimized or omitted. Further since a current can be rapidly transferred in a distributed manner without being concentrated on a specific point, thermal stability can be maintained. When compared with the conventional case using an ITO having a refractive index of 2.0, a total reflection of light generated from the active layer 120 can be more reduced. Thus, light extraction efficiency can be more enhanced, and a flexible light-emitting device can be implemented.

Hereinafter, a light-emitting device 200 manufactured by the method for manufacturing a light-emitting device according to an embodiment of the present invention will be explained.

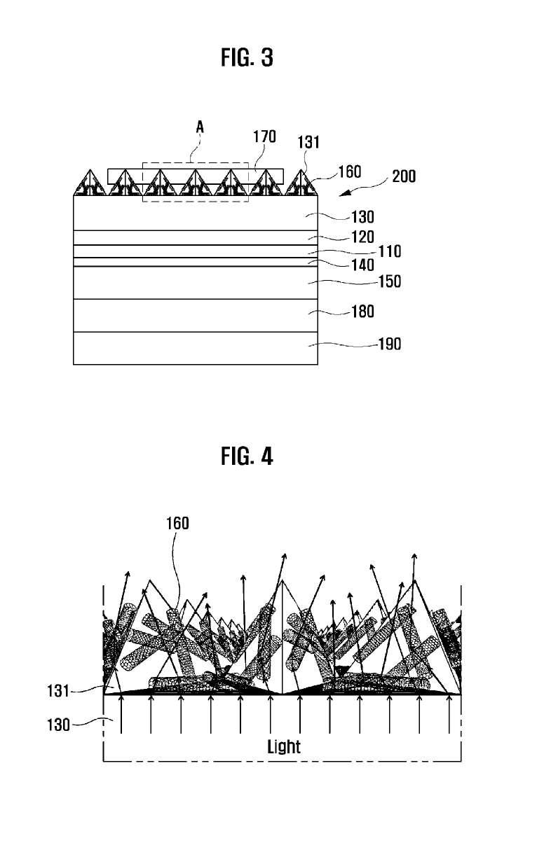

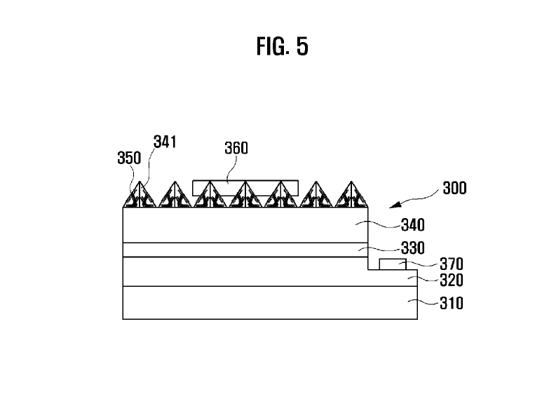

FIG. 3 is a sectional view of a light-emitting device according to an embodiment of the present invention, FIG. 4 is a sectional view illustrating part ‘A’ in FIG. 3, and FIG. 5 is a sectional view illustrating another embodiment of the light-emitting device of FIG. 3.

Referring to FIG. 3, the light-emitting device 200 includes a first conductive semiconductor layer 110, an active layer 120, a second conductive semiconductor layer 130, a transparent conductive layer 140, a reflective layer 150, a nanopattern 160, an electrode 170, an adhesive layer 180 and a support substrate 190.

The first conductive semiconductor layer 110 may be implemented as a ‘p’-type semiconductor layer. The ‘p’-type semiconductor layer may be selected from semiconductor materials having a composition formula of InₓAl_{y}Ga_{1-x-y}N (0≦x≦1, 0≦y≦1, 0≦x+y≦1), e.g., InAlGaN, GaN, AlGaN,AlInN, InGaN, AlN, InN, etc. A ‘p’-type dopant such as Mg, Zn, Ca, Sr and Ba may be doped onto the ‘p’-type semiconductor layer.

The active layer 120 is formed on the first conductive semiconductor layer 110, and may be formed of materials including a semiconductor material having a composition formula of InₓAl_{y}Ga_{1-x-y}N (0≦x≦1, 0≦y≦1, 0≦x+y≦1), for example. The active layer 120 may have one of a single quantum well structure, a multi quantum well (MQW) structure, a quantum point structure and a quantum line structure. The active layer 120 may generate light by energy generated when electrons and holes of the first conductive semiconductor layer 110 and the second conductive semiconductor layer 130 are recombined with each other.

The second conductive semiconductor layer 130 is formed on the active layer 120, and may be implemented as an ‘n’-type semiconductor layer. The ‘n’-type semiconductor layer may be selected from semiconductor materials having a composition formula of InₓAl_{y}Ga_{1-x-y}N (0≦x≦1, 0≦x+y≦1), e.g., InAlGaN, GaN, AlGaN, AlInN, InGaN, AlN, InN, etc. An ‘n’-type dopant such as Si, Ge and Sn may be doped on the ‘n’-type semiconductor layer. The second conductive semiconductor layer 131 includes a light extraction layer 131 having an uneven pattern, on an upper surface thereof. The light extraction layer 131 forms a refraction point for emitting light generated from the active layer 120 to outside without total reflection, by using its uneven pattern. A convex part of the uneven pattern of the light extraction layer 131 may have a triangular conical shape.

The transparent conductive layer 140 is formed on one surface of the first conductive semiconductor layer 110 opposite to another surface thereof where the active layer 120 has been formed. The transparent conductive layer 140, a path along which a current uniformly flows to the first conductive semiconductor layer 110, may be configured as a transparent conducting oxide (TCO) formed of a transparent conductive thin film layer having a metal such as In, Sn and Zn as a host material.

The reflective layer 150 is formed on the transparent conductive layer 140, and may include reflecting materials such as Ag, Ni, Al, Rh, Pd, Ir, Ru, Mg, Zn, Pt and Au, such that light generated from the active layer 120 is emitted to outside of the second conductive semiconductor layer 130.

The nanopattern 160 is formed as the nanomaterials (refer to 30 of FIG. 2C) are partially adsorbed to the light extraction layer 131 having an uneven pattern. The nanopattern 160 forms a plurality of uneven portions on the light extraction layer 131 having an uneven pattern. As a result, an additional refraction point due to the nanopattern 160, as well as a refraction point due to the light extraction layer 131 having an uneven pattern as shown in FIG. 4, can be formed. Thus, the nanopattern 160 can more enhance light extraction efficiency with respect to light generated from the active layer 120.

The electrode 170 is formed on the light extraction layer 131. The electrode 170 may be configured as a single layer or multi layers formed of a material selected from the group consisting of conducting materials for supplying a current to the second conductive semiconductor layer 130, e.g., Ti, Cr, Al, Cu and Au.

The adhesive layer 180 is formed on one surface of the reflective layer 150 opposite to another surface thereof where the transparent conductive layer 140 has been formed. The adhesive layer 180 for attaching the support substrate 190 to the reflective layer 150 may be configured to have a single layer structure or a multi-layer structure, the structure including at least one of Ti, Au, Sn, Ni, Cr, Ga, In, Bi, Cu, Ag and Ta, metallic materials having an excellent bonding characteristic. The adhesive layer 180 may not be formed in a case where the support substrate 190 is formed by a plating or deposition method rather than a bonding method.

The support substrate 190 supports the light-emitting structure 100, and applies a voltage to the light-emitting structure 100 together with the electrode 170. The support substrate 190 may be formed of at least one of a conducting material (e.g., Cu, Au, Ni, Mo and Cu-W) and a carrier wafer (e.g., Si, Ge, GaAs, ZnO, Sic, etc.), such that a current flows to the first conductive semiconductor layer 110.

The light-emitting device 200, manufactured by the method for manufacturing a light-emitting device according to an embodiment of the present invention, is provided with the nanopattern 160 formed as the nanomaterials (refer to 30 of FIG. 2C) are partially adsorbed to the light extraction layer 131. Thus, the light-emitting device 200 can form an additional refraction point due to the nanopattern 160, as well as a reflection point due to the light extraction layer 131 having an uneven pattern. Thus, the light-emitting device 200, manufactured by the method for manufacturing a light-emitting device according to an embodiment of the present invention, can more enhance light extraction efficiency with respect to light generated from the active layer 120.

The light-emitting device 200, manufactured by the method for manufacturing a light-emitting device according to an embodiment of the present invention, is provided with the nanopattern 160 formed by selecting the nanomaterials 30 from transparent materials having excellent conductivity, a refractive index of 1.5˜1.6 and a flexible characteristic, e.g., carbon nano tubes or graphenes. Thus, formation of the electrode 170 can be minimized or omitted. Further, since a current can be rapidly transferred in a distributed manner without being concentrated on a specific point, thermal stability can be maintained. When compared with the conventional case using an ITO having a refractive index of 2.0, a total reflection of light generated from the active layer 120 can be more reduced. Thus, light extraction efficiency can be more enhanced, and a flexible light-emitting device can be implemented.

Referring to FIGS. 3 and 4, the light-emitting device 200 manufactured by the method for manufacturing a light-emitting device according to an embodiment of the present invention is a vertical type light-emitting device. However, as shown in FIG. 5, a light-emitting device 300 manufactured by the method for manufacturing a light-emitting device according to an embodiment of the present invention may be a horizontal type light-emitting device. In this case, the light-emitting device 300, manufactured by the method for manufacturing a light-emitting device according to an embodiment of the present invention, includes a first conductive semiconductor layer 320 formed on a substrate 310, an active layer 330, a second conductive semiconductor layer 340 including a light extraction layer 341 having an uneven pattern at an upper part thereof, a nanopattern 350, and electrodes 360 and 370. The first conductive semiconductor layer 320 may be an ‘n’-type semiconductor layer, and the second conductive semiconductor layer 340 may be a ‘p’-type semiconductor layer. Like the nanopattern 160 of FIG. 3, the nanopattern 350 may be formed as the nanomaterials (refer to 30 of FIG. 2C) are partially adsorbed to the light extraction layer 341 having an uneven pattern.

It will be apparent to those skilled in the art that various modifications and variations can be made in the present invention without departing from the spirit or scope of the invention. Thus, it is intended that the present invention cover modifications and variations of this invention provided they come within the scope of the appended claims and their equivalents.

1. A method for manufacturing a light-emitting device, the method comprising:
a light-emitting structure preparation step for preparing a light-emitting structure including a first conductive semiconductor layer, an active layer, and a second conductive semiconductor layer, which are formed sequentially;
a light extraction layer formation step for forming an upper part of the second conductive semiconductor layer as a light extraction layer having an uneven pattern;
a dipping step for dipping the light-emitting structure having the light extraction layer in a solution in which nanomaterials have been dispersed; and
an adsorption step for adsorbing the nanomaterials to the light extraction layer,
wherein in the adsorption step, the nanomaterials are partially adsorbed to the light extraction layer such that a nanopattern having a plurality of uneven portions is formed on the light extraction layer.

2. The method of claim 1, wherein the adsorption step is performed by a thermal processing method.

3. The method of claim 1, wherein in the dipping step, transparent materials are used as the nanomaterials.

4. The method of claim 3, wherein the nanomaterials are formed of carbon nano tubes or graphenes.

5. The method of claim 1, wherein a convex part of the uneven pattern has a triangular conical shape.

6. The method of claim 1, further comprising forming an electrode on the light extraction layer after the adsorption step.

7. The method of claim 6, wherein in the light-emitting structure preparation step, a transparent conductive layer and a reflective layer are further formed, sequentially on one surface of the first conductive semiconductor layer opposite to another surface thereof where the active layer has been formed.

8. The method of claim 7, further comprising a support substrate attachment step for further forming an adhesive layer and a support substrate, sequentially on one surface of the reflective layer opposite to another surface thereof where the transparent conductive layer has been formed.

9. A light-emitting device, comprising:
a first conductive semiconductor layer;
an active layer formed on the first conductive semiconductor layer;
a second conductive semiconductor layer formed on the active layer, and including a light extraction layer having an uneven pattern at an upper part thereof; and
a nanopattern formed as nanomaterials are partially adsorbed to the light extraction layer,
wherein the nanopattern forms a plurality of uneven portions on the light extraction layer.

10. The light-emitting device of claim 9, wherein the nanomaterials are transparent materials.

11. The light-emitting device of claim 9, wherein the nanomaterials are formed of carbon nano tubes or graphenes.

12. The light-emitting device of claim 9, wherein a convex part of the uneven pattern has a triangular conical shape.

13. The light-emitting device of claim 9, further comprising an electrode formed on the light extraction layer.

14. The light-emitting device of claim 13, further comprising a transparent conductive layer and a reflective layer formed sequentially on one surface of the first conductive semiconductor layer opposite to another surface thereof where the active layer has been formed.

15. The light-emitting device of claim 14, further comprising an adhesive layer and a support substrate sequentially formed on one surface of the reflective layer opposite to another surface thereof where the transparent conductive layer has been formed.

16. The light-emitting device of claim 9, wherein the first conductive type is a ‘p’-type, and the second conductive type is an ‘n’-type.
